(19) United States
(12) Patent Application Publication
(10) Pub. No.: US 2006/0292823 A1
(43) Pub. Date: Dec. 28, 2006

(54) Method and apparatus for bonding wafers

(76) Inventors: Shriram Ramanathan, Portland, OR (US); Mauro J. Kobrinsky, Portland, OR (US)

Correspondence Address: INTEL CORPORATION, P.O. BOX 5326, SANTA CLARA, CA, 95056-5326, US

(21) Appl. No.: 11/169,364

(22) Filed: Jun. 28, 2005

(51) Int. Cl. H01L 21/30; H01L 21/44

(52) U.S. Cl. 438/455; 438/456; 438/459; 438/667; 257/E25.006

(57) ABSTRACT

Embodiments of a method and apparatus for bonding wafers are disclosed. The bonded wafers may include self-passivating interconnects. Other embodiments are described and claimed.

### RELATED APPLICATION

This application is related to U.S. patent application Ser. No. 11/081,187, filed Mar. 16, 2005.

### FIELD OF THE INVENTION

The disclosed embodiments relate generally to wafer bonding and, more particularly, to a method and apparatus for bonding wafers, the wafers perhaps including self passivating interconnects.

### BACKGROUND OF THE INVENTION

Three-dimensional wafer bonding, or wafer stacking, is the bonding together of two or more semiconductor wafers upon which integrated circuitry has been formed. The wafer stack that is formed is subsequently diced into separate stacked die, each stacked die having multiple layers of integrated circuitry. Wafer stacking may offer a number of potential benefits. For example, integrated circuit (IC) devices formed by wafer stacking may provide enhanced performance and functionality while perhaps lowering costs and improving form factors. System-on-chip (SOC) architectures formed by wafer stacking can enable high bandwidth connectivity between stacked die with dissimilar technologies—e.g., logic circuitry and dynamic random access memory (DRAM)—that otherwise have incompatible process flows. Also, by using three-dimensional wafer bonding, smaller die sizes may be achieved, which can reduce interconnect delays. There are many potential applications for wafer stacking technology, including high performance processing devices, video and graphics processors, high density and high bandwidth memory chips, the aforementioned SOC solutions, as well as others.

One method for three-dimensional wafer bonding is metallic bonding. In metallic wafer bonding, two wafers are joined by bonding metal bond structures formed on one of the wafers with corresponding metal bond structures formed on the other wafer. For example, a number of copper bond pads may be formed on a first wafer and a corresponding number of copper bond pads may be formed on a second wafer. The first and second wafers are aligned and brought together, such that each of the copper pads on the first wafer mates with a corresponding one of the copper pads on the second wafer. A bonding process is then performed (e.g., as by application of pressure and/or elevated temperature) to join the mating bond pads, thereby forming a plurality of interconnects between the first and second wafers, which now form a wafer stack. Each of the first and second wafers includes integrated circuitry for a plurality of die, and the wafer stack is cut into a number of stacked die. Each stacked die comprises one die from the first wafer and another die from the second wafer, these die being mechanically and electrically coupled by some of the previously formed interconnects.

### BRIEF DESCRIPTION OF THE DRAWINGS

FIG. 1 is a schematic diagram illustrating an embodiment of a method of forming self-passivating interconnects.

FIGS. 2A-2D are schematic diagrams illustrating embodiments of the method of FIG. 1.

FIGS. 3A-3C are schematic diagrams illustrating various embodiments of bond structures which may be used to form self-passivating interconnects.

FIG. 4 is a schematic diagram illustrating an embodiment of the alignment and bonding of two bond structures, as shown in FIG. 2C.

FIG. 5A is a schematic diagram illustrating an embodiment of a wafer stack, which may include self-passivating interconnects.

FIG. 5B is a schematic diagram illustrating a cross-sectional view of the wafer stack of FIG. 5A, as taken along line B-B of FIG. 5A.

FIG. 6 is a schematic diagram illustrating an embodiment of a computer system, which may include a component formed according to the disclosed embodiments.

FIG. 7 is a schematic diagram illustrating an embodiment of a method for bonding wafers, wherein the wafers may include self-passivating interconnects.

FIG. 8A-8E are schematic diagrams illustrating embodiments of the method of FIG. 7.

FIGS. 9A-9B are schematic diagrams illustrating embodiments of the method of FIG. 7.

FIG. 10 is a schematic diagram illustrating an embodiment of an apparatus for bonding wafers.

### DETAILED DESCRIPTION OF THE INVENTION

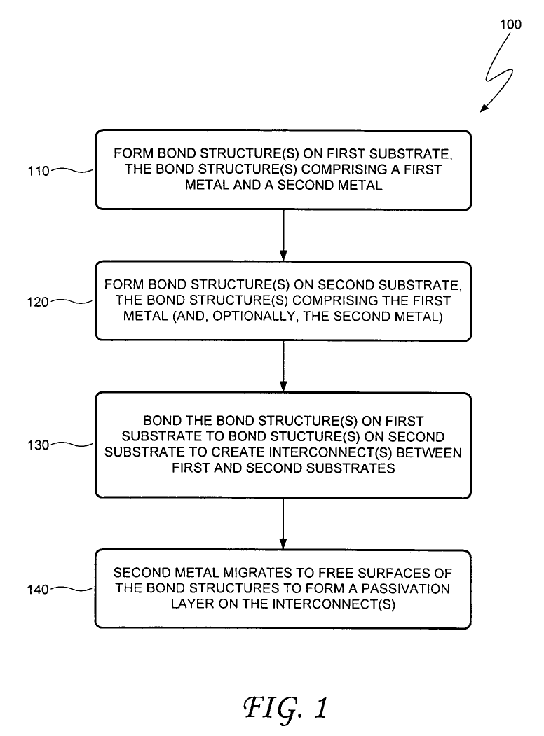

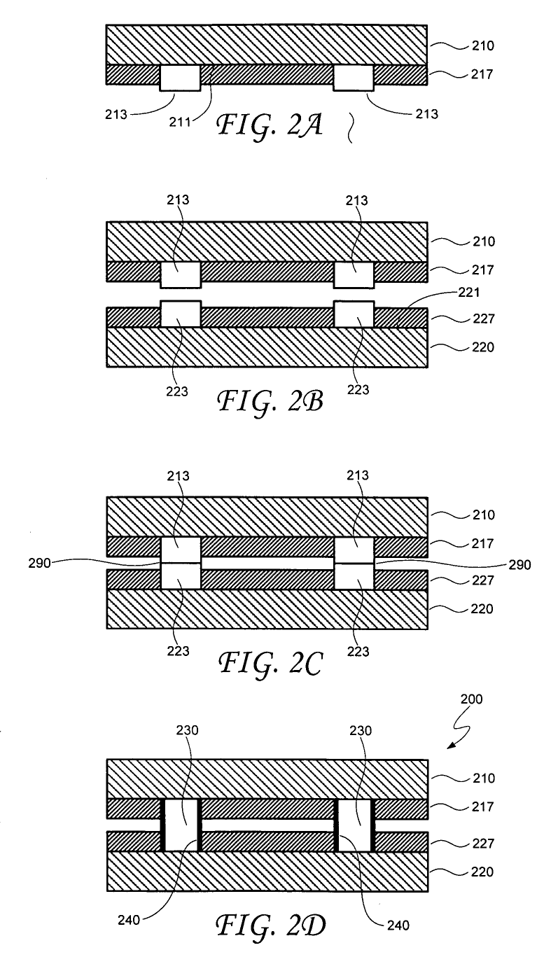

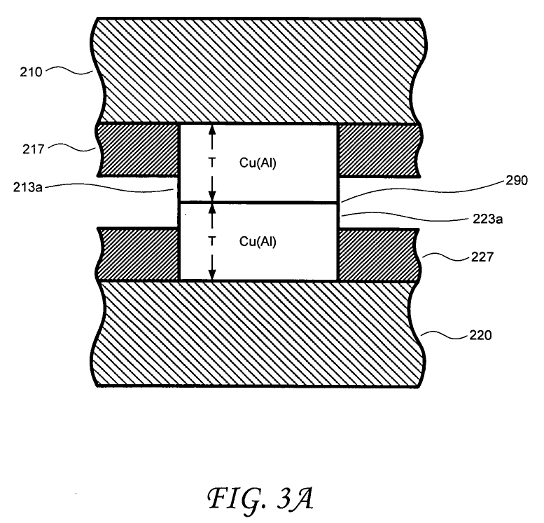

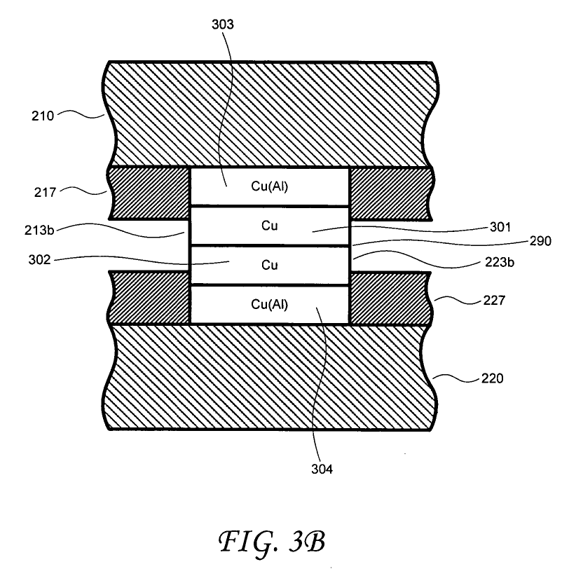

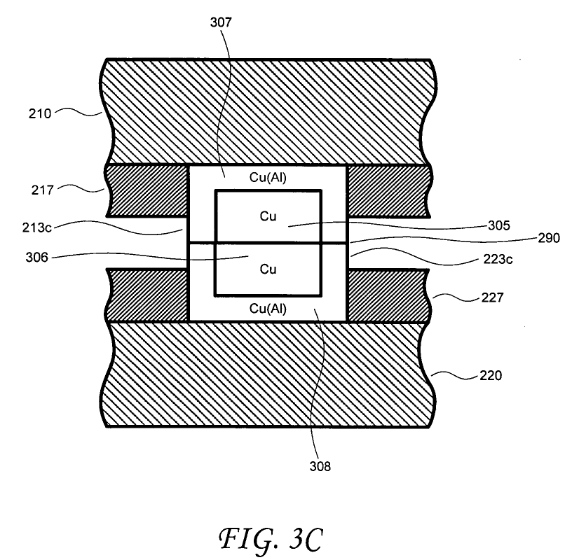

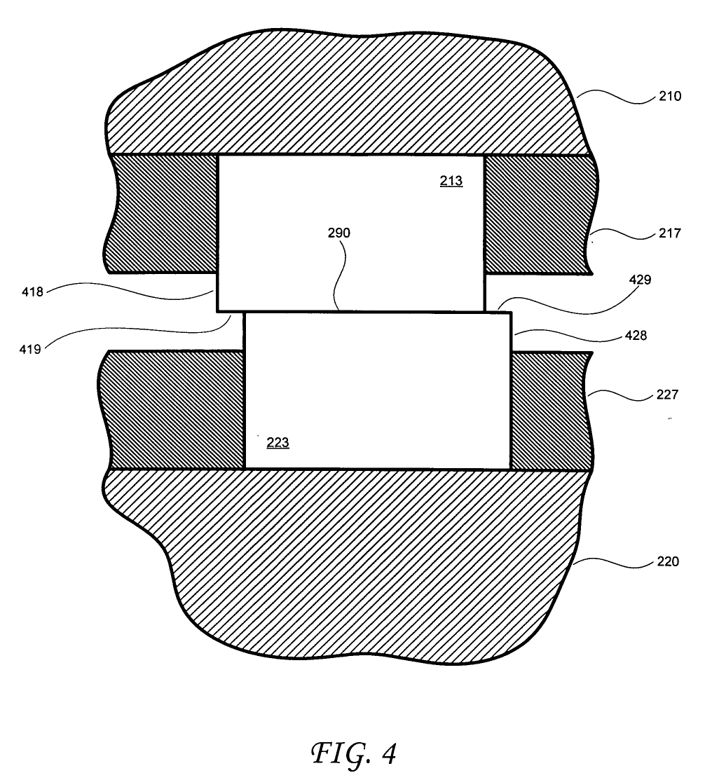

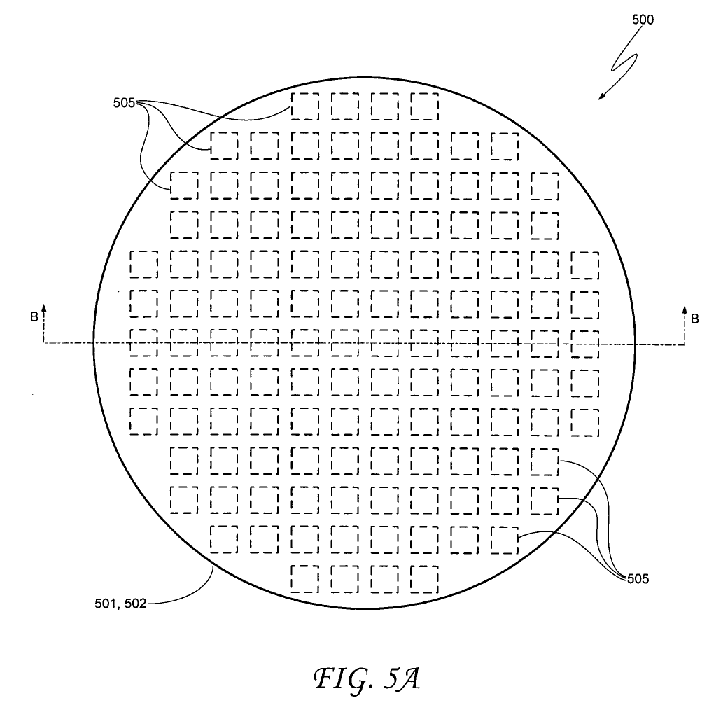

Referring to FIG. 1, illustrated is an embodiment of a method of forming self-passivating interconnects. Embodiments of the method of FIG. 1 are further illustrated in FIGS. 2A-2D, as well as FIGS. 3A-3C and FIG. 4, and reference should be made to these figures as called out in the text below.

With reference now to block 110 in FIG. 1, one or more bond structures are formed on a first substrate, each of these bond structures comprising, at least in part, a first metal and a second metal (or other element). This is illustrated in FIG. 2A, which shows a first substrate 210 having a surface 211 upon which a number of bond structures 213 have been formed. Each of the bond structures 213 may be electrically coupled with a conductor formed in the substrate 210. In one embodiment, the substrate 210 comprises a semiconductor wafer upon which integrated circuitry has been formed for a number of die. A layer of dielectric material 217 may also be disposed on the surface 211 of first substrate 210. The dielectric layer 217 may comprise any suitable dielectric material, such as SiO₂, Si₃N₄, Carbon-doped Oxide (CDO), SiOF, or a spun-on material (e.g., a spun-on glass or polymer). In one embodiment, the bond structures 213 extend above an outer surface of the dielectric layer 217 (e.g., as may be achieved by polishing or etching back the dielectric layer).

As noted above, the bond structures 213 comprise, at least in part, an alloy of a first metal and a second metal (or other element). The first metal comprises an electrically conductive metal that will ultimately form part of an electrically conductive interconnect. In one embodiment, the first metal comprises copper. However, the first metal may comprise any other suitable electrically conductive metal (e.g., aluminum, gold, silver, etc.) or conductive metal alloy. Also, as suggested above, only a portion of each bond structure 213 may comprise an alloy of the first and second metals, whereas other portions of the bond structures may comprise substantially the first metal, as will be explained below in greater detail with respect to FIGS. 3A-3C.

The second metal or element comprises any metal (or other material) having the ability to form a passivation layer over the interconnect that is to be formed. In one embodiment, the second metal comprises a substance that can diffuse through the first metal, such that the second metal can migrate to free surfaces of the interconnect structure to form the passivation layer. Metals believed suitable for the second metal include, but are not limited to, aluminum, cobalt, tin, magnesium, and titanium. In one embodiment, the second element comprises a non-metal. According to one embodiment, the amount of the second metal (or element) present in the alloy (of the first and second metals) is at or below the solubility limit of the second metal in the first metal. In one embodiment, the content of the second metal in the metal alloy is between 0.1 and 10 atomic percent. For example, should the first metal comprise copper and the second metal aluminum, the amount of aluminum present in the Cu(Al) alloy is up to approximately 3 atomic percent.

According to another embodiment, at room temperature, the diffusion mechanism that enables migration of the second metal (or element) within the first metal is slow or substantially non-existent, such that the second metal is “trapped” within the lattice structure of the first metal, which can prevent early formation of the passivation layer. Premature formation of the passivation layer (e.g., before bonding of the bond structures 213 with the bond structures of a second substrate, as will be described below) can potentially hinder metallic bonding. At elevated temperature, however, the second metal (or element) is able to diffuse through the first metal, such that the second metal can segregate to the free surfaces of the interconnect structure to form a passivation layer. The tendency of some metals, when alloyed with another metal, to migrate to free surfaces is a well known phenomena and is not discussed further.

In a further embodiment, the bond structure 213 comprises the first metal and two or more additional metals (or other elements). Each of these additional metals (or elements) comprises a substance that can diffuse through the first metal to form the passivation layer. Thus, the passivation layer may comprise a combination of the two (or more) additional metals or other elements.

In one embodiment, the passivation layer is formed in the presence of an environment including oxygen, and the passivation layer comprises an oxide of the second metal (e.g., Al₂O₃). According to another embodiment, the passivation layer is formed in the presence of an environment including nitrogen, and the passivation layer comprises a nitride of the second metal (e.g., AlN). In yet another embodiment, the passivation layer comprises substantially the second metal (or other material).

Referring to block 120 in FIG. 1, one or more bond structures are formed on a second substrate, each of these bond structures comprising the first metal. The bond structures on the second substrate may optionally include the second metal (or other element or elements), such that at least a portion of each bond structure comprises an alloy of the first and second metals. This is illustrated in FIG. 2B, which shows a second substrate 220 having a surface 221 upon which a number of bond structures 223 have been formed. Each of the bond structures 223 may be electrically coupled with a conductor formed in the substrate 220. In one embodiment, the substrate 220 comprises another semiconductor wafer upon which integrated circuitry has been formed for a corresponding number of die. A layer of dielectric material 227 may also be disposed on the surface 221 of second substrate 220. The dielectric layer 227 may comprise any suitable dielectric material, such as SiO₂, Si₃N₄, CDO, SiOF, or a spun-on material (e.g., a spun-on glass or polymer). In one embodiment, the bond structures 223 extend above an outer surface of the dielectric layer 227 (e.g., as may be achieved by polishing or etching back the dielectric layer).

The bond structures 223 on second substrate 220 will be aligned and mated with the bond structures 213 on first substrate 210, and a bonding process will be performed to form interconnects between the first and second substrates. Each of these interconnects will be formed from a bond structures 213 on first substrate 210 and a mating bond structure 223 on second substrate 220, and a passivation layer will be formed over each interconnect from the second metal (or element or combination of other metals and/or elements). As noted above, the bond structures 223 on second substrate may comprise substantially the first metal (without the second metal). According to this embodiment, just one of the mating bond structures (e.g., bond structure 213 or, perhaps, bond structure 223) includes the second metal, and the passivation layer is formed from the second metal present in this one bond structure. According to another embodiment, however, the bond structures 223 on second substrate 220 comprise, at least in part, an alloy of a first metal and a second metal. Thus, the passivation layer that is ultimately created on each interconnect is formed from the second metal that is present in each of the mating bond structures 213, 223 of the first and second substrates 210, 220, respectively. The characteristics of the first and second metals (or elements) were described above.

The bond structures 213, 223 on the first and second substrates 210, 220 may have any suitable shape, so long as a bond structure 213 on first substrate 210 can be mated and bonded to a bond structure 223 on second substrate 220 to form an interconnect extending between these two substrates. In one embodiment, each of the bond structures 213, 223 comprises a circular-shaped or a square-shaped bond pad. However, it should be understood that the disclosed embodiments are not limited to the formation of such bond pads and, further, that the bond structures 213, 223 may comprise any other suitable shape (e.g., spherical bumps). In one embodiment, the bond structures 213, 223 have a thickness T (see FIG. 3A) of between 0.1 μm and 10 μm. The bond structures 213, 223 may also be formed by any suitable process or processes. Various embodiments of the bond structures 213, 223 are described below in greater detail with respect to FIGS. 3A-3C.

Returning again to FIG. 1, and block 130 in particular, the bond structures of the first and second substrates are aligned and brought into contact for bonding, such that the bond structures on the first substrate can be bonded with the bond structures on the second substrate to form interconnects between the first and second substrates. This is further illustrated in FIG. 2C, where the first and second substrates 210, 220 have been aligned and brought together for bonding. Each of the bond structures 213 on first substrate 210 has been aligned and mated with a corresponding one of the bond structures 223 on the second substrate 220.

Various embodiments of the bond structures 213, 223, after alignment and contact, are illustrated in FIGS. 3A through 3C. Turning first to FIG. 3A, embodiments of bond structures 213a, 223a are shown. The entire bond structures 213a, 223a (or a substantial portion of these structures) comprise an alloy of the first and second metals (e.g., an alloy of copper and aluminum). The bond structures 213a may be formed by first depositing the layer of dielectric material 217 over the substrate 210, and then forming vias or other apertures (e.g., as by a mask and etching process) into the dielectric layer 217 at locations of the bond structures. The alloy of the first and second metals is then deposited in the vias (e.g., as by a blanket deposition step followed by a planarization step, such as chemical-mechanical polishing) to form the bond structures 213a. The dielectric layer 217 may also be polished or etched back to expose the upper portion of the bond structure, as shown in FIG. 3A. The bond structures 223a on substrate 220 may be formed in a similar fashion.

Referring to FIG. 3B, further embodiments of bond structures 213b, 223b are illustrated. The bond structure 213b includes an upper portion 301 that comprises substantially the first metal (e.g., copper), as well as a lower portion 303 that comprises an alloy of the first and second metals (e.g., copper and aluminum). Similarly, the bond structure 223b includes an upper portion 302 that comprises substantially the first metal and a lower portion 304 comprising the alloy of the first and second metals. The bond structure 213b may be formed by first depositing the layer of dielectric material 217 over the substrate 210, and then forming vias or other apertures (e.g., as by a mask and etching process) into the dielectric layer 217 at locations of the bond structures. A layer of the alloy of the first and second metals is then deposited in the vias (e.g., as by selective deposition onto conductors in substrate 210 that underlie locations of the bond structures) to form the lower portion 303 of the bond structure. A layer of the first metal is then deposited over the alloy layer (e.g., as by selective deposition onto the alloy layer previously deposited in each via and, perhaps, a subsequent planarization step) to form the upper portion 301 of the bond structures 213a. The dielectric layer 217 may also be polished or etched back to expose the upper portion of the bond structure, as shown in FIG. 3B. The bond structures 223b on substrate 220 may be formed in a similar manner.

Referring next to FIG. 3C, additional embodiments of bond structures 213c, 223c are shown. The bond structure 213c includes an interior portion 305 comprised of substantially the first metal (e.g., copper). The interior portion 305 of bond structure 213c is surrounded by an outer portion 307 comprised of an alloy of the first and second metals (e.g., copper and aluminum). Similarly, the bond structure 223c includes an interior portion 306 comprised substantially of the first metal, with the interior portion 306 being surrounded by an outer portion 308 that is comprised of the alloy of the first and second metals. The bond structure 213c may be formed by first depositing the layer of dielectric material 217 over the substrate 210, and then forming vias or other apertures (e.g., as by a mask and etching process) into the dielectric layer 217 at locations of the bond structures. A seed layer of the alloy of the first and second metals may then be deposited in the vias (e.g., as by a blanket deposition process) to form the outer portion 307 of the bond structure. A layer of the first metal is then deposited over the alloy layer (e.g., as by a subsequent blanket deposition step, which may be followed by a planarization step) to form the interior portion 305 of the bond structures 213c. The dielectric layer 217 may also be polished or etched back to expose the upper portion of the bond structure, as shown in FIG. 3C. The bond structures 223c on substrate 220 may be formed in a similar manner.

In each of FIGS. 3A-3C, the bond structures 213, 223 are the same. It should be understood, however, that the bond structures on the first and second substrates 210, 220 may not be the same. For example, the first substrate 210 may have bond structures similar to those shown in FIG. 3A, whereas the second substrate 220 may have bond structures similar to those shown in FIG. 3B. By way of further example, the first substrate 210 may have bond structures similar to those shown in any one of FIGS. 3A through 3C, whereas the second substrate 220 may have bond structures that are substantially comprised of the first metal (e.g., copper). The reader will appreciate that any combination of mating bond structures may be used, depending upon the desired characteristics and operating environment of the interconnects that are to be formed.

During bonding, the bond structures 213 on first substrate 210 are to be bonded with the bond structures 223 on second substrate 220 to form interconnects extending between these two substrates. For optimal bonding, it may in some embodiments be desirable to inhibit formation of a passivation layer at the interfaces between the bond structures 213, 223 (see reference numeral 290 in FIGS. 2C, 3A-3C, and 4). Thus, according to one embodiment, it may be desirable to delay migration of the second metal to the interface surfaces of the bond structures 213, 223 until bonding between the bond structures has been achieved. This may, in one embodiment, be accomplished by placing at interface 290 material that comprises substantially the first metal (e.g., copper). Each of FIGS. 3B and 3C are examples of bond structures (213b, 223b and 213c, 223c) which provide a layer (or quantity) of the first metal at the interface 290 between the bond structures. This layer (or quantity) of first metal at the interface 290 essentially serves as a delay function that slows the migration of the second metal to the interface prior to bonding. In yet another embodiment, one or more additional layers of metal (or other element) may be disposed between the metal layers to further delay migration of the second metal to the interface prior to bonding (e.g., in each of FIGS. 3B and 3C, an additional layer of material may be disposed between the Cu(Al) and Cu layers).

The alignment of two bond structures 213, 223 is further illustrated in FIG. 4. Referring to this figure, when two of the bond structures 213, 223 are aligned and placed in contact, there will be a number of free surfaces (e.g., an exterior surface of a bond structure) exposed to the ambient environment. These exposed free surfaces include surfaces 418, 428 of the bond structures 213, 223 that extend above their respective dielectric layers 217, 227. In addition, due to misalignment between the bond structures 213, 223, exposed free surfaces 419, 429 may also exist at the interface 290. After bonding of the bond structures 213, 223 to form an interconnect, these free surfaces 418, 428, 419, 429 may remain exposed to the external environment, making them susceptible to oxidation and corrosion. However, the passivation layer that is to be formed during or after bonding (from migration of the second metal to these free surfaces) can inhibit such oxidation and corrosion (although the passivation layer itself may be formed, in part, by an oxidation process).

Bonding may take place under any suitable process conditions. In one embodiment, the bond structures 213, 223 on the first and second substrates 210, 220 are brought in contact under pressure and subjected to an elevated temperature. According to one embodiment, the contact pressure between the bond structures 213, 223 is in a range up to 5 MPa, and bonding is performed at a temperature up to 450 degrees Celsius. The ambient environment in which bonding occurs may also affect bonding, as well as the formation of the passivation layer. In one embodiment, bonding is performed in an atmosphere including oxygen, in which case the passivation layer formed may be an oxide of the second metal (e.g., Al₂O₃). In another embodiment, bonding is performed in an atmosphere including nitrogen, and the passivation layer formed may be a nitride of the second metal (e.g., AlN). In a further embodiment, bonding is performed under a vacuum, and the passivation layer formed may comprise substantially the second metal (although subsequent oxidation of the passivation layer may occur if the bonded substrates are not hermetically sealed). These are but a few examples of the conditions under which bonding may be performed, and the reader will appreciate that other process conditions may be employed, depending upon the desired characteristics of the interconnects being formed.

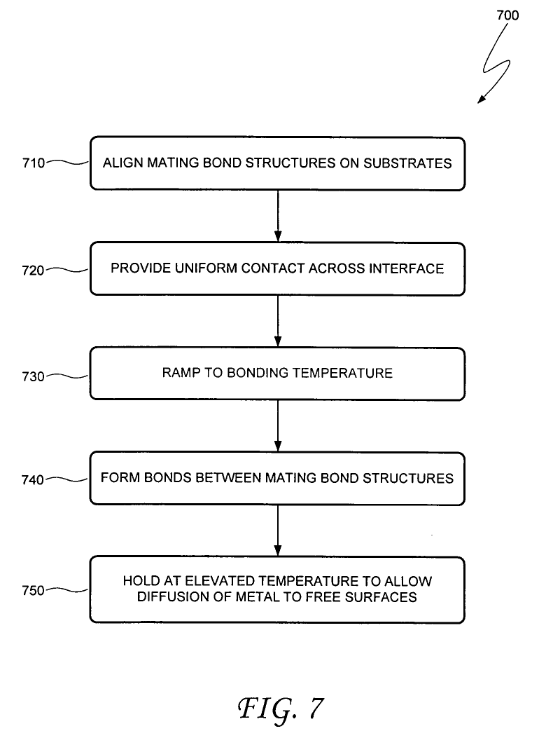

Embodiments of a method and apparatus for bonding wafers are described in FIG. 7 through 10 and the accompanying text below. However, it should be understood that the methods and apparatus disclosed in FIGS. 7 through 10 are but examples of a method and apparatus for bonding wafers having self-passivating interconnect structures. Thus, it should be understood that the disclosed embodiments for forming self-passivating interconnects are not limited to any particular method and/or apparatus for wafer bonding (and, further, that these embodiments are applicable outside the field of wafer bonding).

During bonding, two processes should occur: (1) the formation of a metallic bond between the mating bond structures 213, 223 to form interconnects extending between the first and second substrates 210, 220 (see block 130); and (2) migration of the second metal to free surfaces (see FIG. 4) of the bond structures 213, 223 to form a passivation layer over each of the interconnects, as is set forth in block 140 of FIG. 1. This is further illustrated in FIG. 2D, which shows interconnects 230 that have been formed from the mating bond structures 213, 223, which are now bonded to one another. As also shown in FIG. 2D, a passivation layer 240 has been formed over each of the interconnects 230, this passivation layer 240 being formed from the second metal (e.g., either an oxide or nitride of the second metal, or perhaps formed substantially of the second metal). In one embodiment, each of the interconnects 230 comprises substantially the first metal; however, in other embodiments, some of the second metal may remain within the interconnects 230 (e.g., some of the second metal may remain “trapped” in the lattice structure of the first metal because bonding was stopped prior to segregation of all of the second metal to the free surfaces). The two aforementioned processes—e.g., bonding and passivation layer formation—may, in one embodiment, occur simultaneously (or nearly simultaneous). In other embodiments, however, these two processes may occur sequentially (e.g., bonding may occur first followed by migration of the second metal to the free surfaces and formation of a passivation layer).

The thickness of the passivation layer 240 will be a function of the choice of the first and second metals, as well as the processing conditions under which this layer forms (e.g., the atmosphere, temperature and time, etc.). This thickness may be specified to achieve desired characteristics for the passivation layer 240 (e.g., corrosion resistance, electromigration resistance, electrical isolation, etc.). According to one embodiment, the passivation layer 240 on the interconnects 230 has a thickness of between approximately 5 and 1,000 Angstroms. For example, where the passivation layer 240 comprises Al₂O₃ (and the interconnect substantially copper), the passivation layer may have a thickness of approximately 30 Angstroms. By way of further example, where the passivation layer 240 comprises AlN (and the interconnect substantially copper), the passivation layer may have a thickness of approximately 100 Angstroms. The reader will appreciate that other thicknesses can be achieved, as desired.

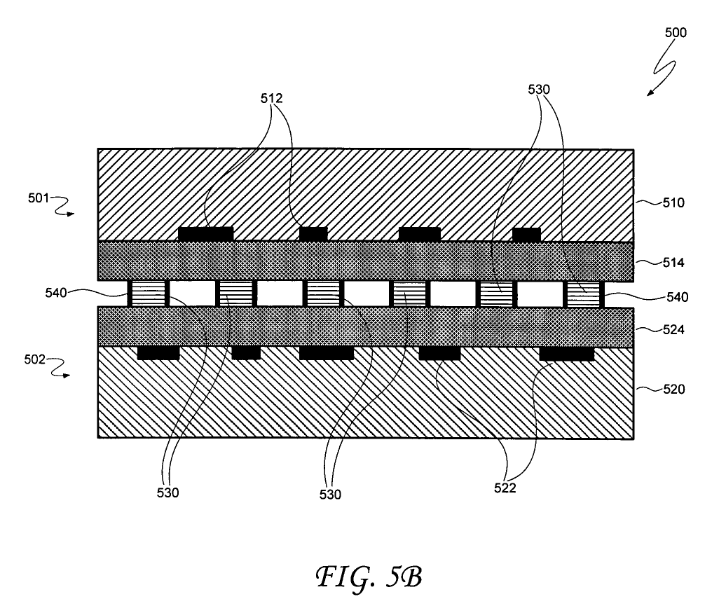

As previously suggested, the above-described embodiments for forming self-passivating interconnects may be used to bond together semiconductor wafers to form a wafer stack. An embodiment of such a wafer stack 500 is illustrated in FIGS. 5A and 5B, wherein FIG. 5B shows a cross-sectional view of the wafer stack of FIG. 5A, as taken along line B-B of FIG. 5A. Referring to these figures, a wafer stack 500 includes a first wafer 501 and a second wafer 502, each of the wafers 501, 502 comprising a substrate 510, 520, respectively. The substrate 510, 520 of each wafer 501, 502 typically comprises a semiconductor material, such as Silicon (Si), Silicon-on-Insulator (SOI), Gallium Arsenide (GaAs), etc. Integrated circuitry for a number of stacked die 505 has been formed on each of the wafers 501, 502, and the wafer stack 500 is ultimately cut into these separate stacked die 505. The integrated circuitry for each stacked die 505 may include a number of active devices 512 (e.g., transistors, capacitors, etc.) formed on the substrate 510 of first wafer 501 and a number of active devices 522 formed on the substrate 520 of second wafer 502.

Disposed over a surface of first wafer 501 is an interconnect structure 514, and disposed over a surface of the second wafer 502 is an interconnect structure 524. Generally, each of the interconnect structures 514, 524 comprises a number of levels of metallization, each layer of metallization separated from adjacent levels by a layer of dielectric material (or other insulating material) and interconnected with the adjacent levels by vias. The dielectric layers of interconnects 514, 524 are often each referred to as an “interlayer dielectric” (or “ILD”), and the ILD layers may comprise any suitable insulating material, such as SiO₂, Si₃N₄, CDO, SiOF, or a spun-on material (e.g., a spun-on glass or polymer). The metallization on each layer comprises a number of conductors (e.g., traces) that may route signal, power, and ground lines to and from the integrated circuitry of each die 505, and this metallization comprises a conductive material, such as copper, aluminum, silver, gold, as well as alloys of these (or other) materials.

Disposed between the first and second wafers 501, 502, and both mechanically and electrically coupling these two wafers together, is a number of interconnects 530. Formed over each of the interconnects is a passivation layer 540. According to one embodiment, the interconnects 530 comprise substantially copper, and the passivation layer 540 comprises aluminum. According to another embodiment, the passivation layer comprises aluminum oxide, and in a further embodiment the passivation layer comprises aluminum nitride. In one embodiment, the interconnects are self-passivating, and they are formed according to one or more of the above-described embodiments.

In one embodiment, the first and second wafers 501, 502 have the same size and shape; however, in another embodiment, these wafers have differing shapes and/or sizes. In one embodiment, the first and second wafers 501, 502 comprise the same material, and in a further embodiment, the first and second wafers 501, 502 comprise different materials. Also, although the wafers 501, 502 may be fabricated using substantially the same process flow, in another embodiment, the wafers 501, 502 are fabricated using different process flows. In one embodiment, one of the wafers (e.g., wafer 501) includes logic circuitry formed using a first process flow, and the other wafer (e.g., wafer 502) includes memory circuitry (e.g., DRAM, SRAM, etc.) that is formed using a second, different process flow. Thus, as the reader will appreciate, the disclosed embodiments are applicable to any type of wafer or combination of wafers—irrespective of size, shape, material, architecture, and/or process flow—and, as used herein, the term “wafer” should not be limited in scope to any particular type of wafer or wafer combination.

Ultimately, the wafer stack 500 will be cut into a number of separate stacked die 505, as noted above. Each stacked die will include a die from first wafer 501 and a die from the second wafer 502. These two stacked die will be interconnected—both electrically and mechanically—by some of the interconnects 530.

The above-described embodiments for forming self-passivating interconnects have been explained, at least in part, in the context of forming a three-dimensional wafer stack. However, it should be understood that the disclosed embodiments are not limited in application to wafer stacking and, further, that the disclosed embodiments may find use in other devices or applications. For example, the above-described embodiments may be used to form self-passivating interconnects between a integrated circuit die and a package substrate, and/or to form self-passivating interconnects between a package and a circuit board. The above-described embodiments may also find application to wafer-to-die bonding and to die-to-die bonding.

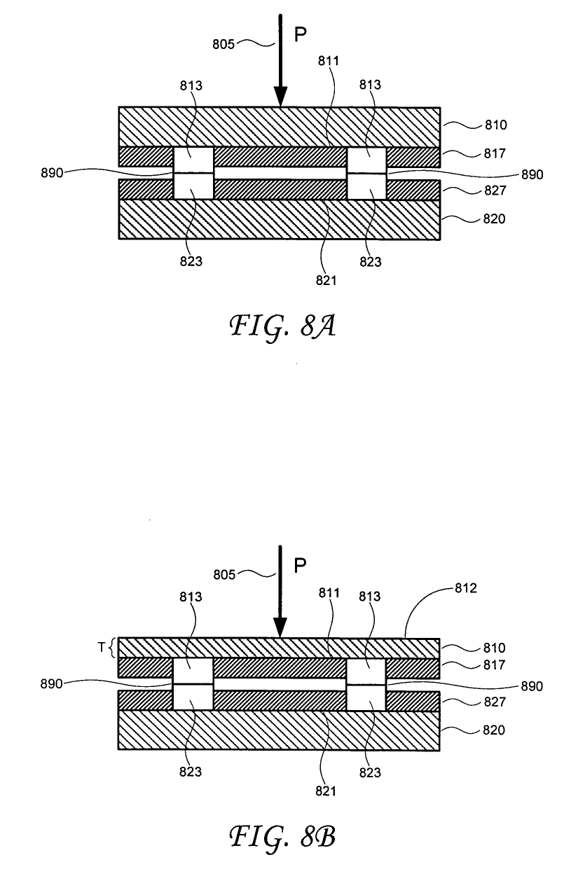

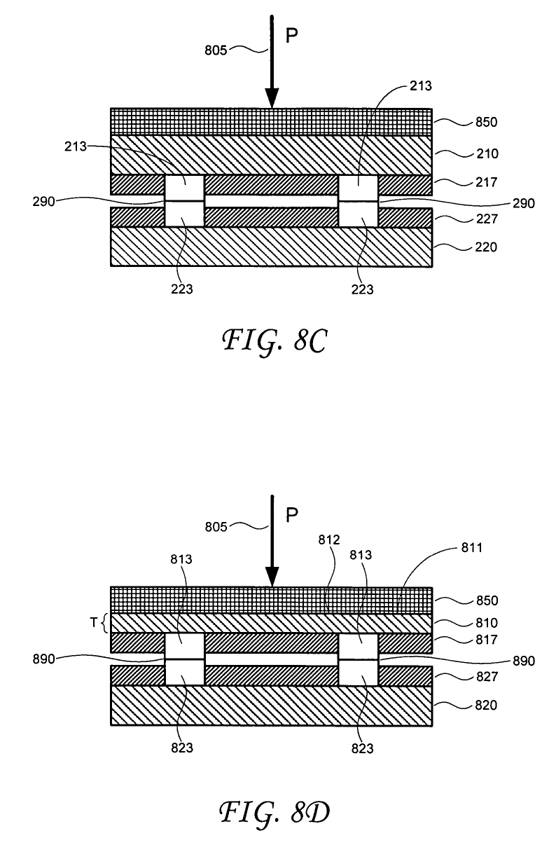

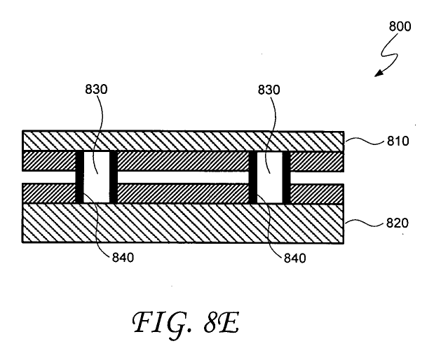

Also, it should be noted that, in FIGS. 2A-2D (as well as FIGS. 8A-8E, which are discussed below), a limited number of bond structures and interconnects are shown for ease of illustration. Similarly, in FIGS. 5A-5B, only a limited number interconnects 530, as well as active devices 512, 522, are shown for ease of illustration and clarity. However, as the reader will appreciate, the substrates 210, 220 of FIGS. 2A-2D (and substrates 810, 820 of FIGS. 8A-8E) and the semiconductor wafers 501, 502 of FIGS. 5A-5B may include thousands or perhaps millions of such interconnects (230 or 530). Similarly, the integrated circuitry formed on wafers 501, 502 for each stacked die 505 may, in practice, include tens of millions, or even hundreds of millions, of active devices 512, 522 (e.g., transistors). Thus, it should be understood that FIGS. 2A-2D and 5A-5B (as well as FIGS. 8A-8E) are simplified schematic representations presented merely as an aid to understanding the disclosed embodiments and, further, that no unnecessary limitations should be drawn from these schematic representations.

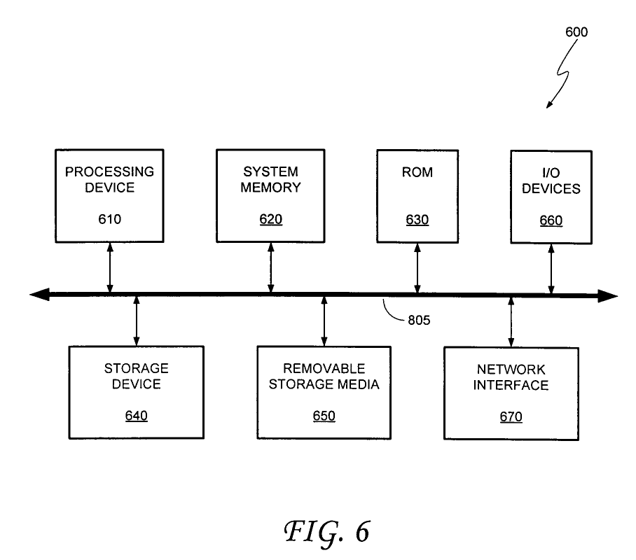

Referring to FIG. 6, illustrated is an embodiment of a computer system 600. Computer system 600 includes a bus 605 to which various components are coupled. Bus 605 is intended to represent a collection of one or more buses—e.g., a system bus, a Peripheral Component Interface (PCI) bus, a Small Computer System Interface (SCSI) bus, etc.—that interconnect the components of system 600. Representation of these buses as a single bus 605 is provided for ease of understanding, and it should be understood that the system 600 is not so limited. Those of ordinary skill in the art will appreciate that the computer system 600 may have any suitable bus architecture and may include any number and combination of buses.

Coupled with bus 605 is a processing device (or devices) 610. The processing device 610 may comprise any suitable processing device or system, including a microprocessor, a network processor, an application specific integrated circuit (ASIC), or a field programmable gate array (FPGA), or similar device. It should be understood that, although FIG. 6 shows a single processing device 610, the computer system 600 may include two or more processing devices.

Computer system 600 also includes system memory 620 coupled with bus 605, the system memory 620 comprising, for example, any suitable type and number of memories, such as static random access memory (SRAM), dynamic random access memory (DRAM), synchronous DRAM (SDRAM), or double data rate DRAM (DDRDRAM). During operation of computer system 600, an operating system and other applications may be resident in the system memory 620.

The computer system 600 may further include a read-only memory (ROM) 630 coupled with the bus 605. The ROM 630 may store instructions for processing device 610. The system 600 may also include a storage device (or devices) 640 coupled with the bus 605. The storage device 640 comprises any suitable non-volatile memory, such as, for example, a hard disk drive. The operating system and other programs may be stored in the storage device 640. Further, a device 650 for accessing removable storage media (e.g., a floppy disk drive or a CD ROM drive) may be coupled with bus 605.

The computer system 600 may also include one or more I/O (Input/Output) devices 660 coupled with the bus 605. Common input devices include keyboards, pointing devices such as a mouse, as well as other data entry devices, whereas common output devices include video displays, printing devices, and audio output devices. It will be appreciated that these are but a few examples of the types of I/O devices that may be coupled with the computer system 600.

The computer system 600 may further comprise a network interface 670 coupled with bus 605. The network interface 670 comprises any suitable hardware, software, or combination of hardware and software that is capable of coupling the system 600 with a network (e.g., a network interface card). The network interface 670 may establish a link with the network (or networks) over any suitable medium—e.g., wireless, copper wire, fiber optic, or a combination thereof—supporting the exchange of information via any suitable protocol—e.g., TCP/IP (Transmission Control Protocol/Internet Protocol), HTTP (Hyper-Text Transmission Protocol), as well as others.

It should be understood that the computer system 600 illustrated in FIG. 6 is intended to represent an exemplary embodiment of such a system and, further, that this system may include many additional components, which have been omitted for clarity and ease of understanding. By way of example, the system 600 may include a DMA (direct memory access) controller, a chip set associated with the processing device 810, additional memory (e.g., a cache memory), as well as additional signal lines and buses. Also, it should be understood that the computer system 600 may not include all of the components shown in FIG. 6.

In one embodiment, the computer system 600 includes a component having a stacked die including self-passivating interconnects formed according to one or more of the above-described embodiments. For example, the processing device 610 of system 600 may include such a stacked die with self passivating interconnects. However, it should be understood that other components of system 600 (e.g., network interface 670, etc.) may include a device having a component with self-passivating interconnects.

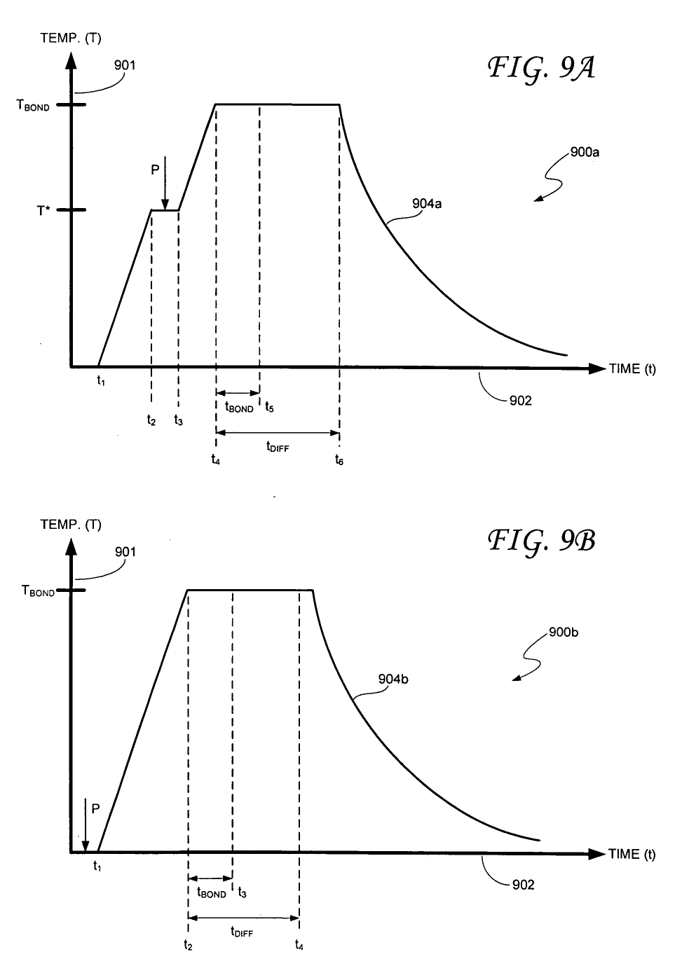

Referring now to FIG. 7, illustrated is an embodiment of a method of bonding wafers, the bonded wafers including, in one embodiment, self-passivating interconnects. Embodiments of the method of FIG. 7 are further illustrated in FIGS. 8A-8E, as well as FIGS. 9A and 9B, and reference should be made to these figures as called out in the text below.

As set forth in block 710 in FIG. 7, the mating bond structures of two substrates are aligned. This is illustrated in FIG. 8A, which shows a first substrate 810 and a second substrate 820. In one embodiment, each of the substrates 810, 820 comprises a semiconductor wafer upon which integrated circuitry has been formed for a number of die. A number of bond structures 813 have been formed on a surface 811 of the first substrate 810, and a mating number of bond structures 823 have been formed on a surface 821 of the second substrate 820. A layer of dielectric material 817, 827 may also be disposed on the surfaces 811, 821 of first and second substrates 810, 820, respectively. The dielectric layers 817, 827 may comprise any suitable dielectric material, such as SiO₂, Si₃N₄, CDO, SiOF, or a spun-on material (e.g., a spun-on glass or polymer). In one embodiment, the bond structures 813, 823 extend above an outer surface of the dielectric layers 817, 827, respectively (e.g., as may be achieved by polishing or etching back the dielectric layer).

The mating bond structures 813, 823 of the first and second wafers 810, 820 have been aligned and brought into contact, as shown in FIG. 8A. According to one embodiment, the bond structures 813, 823 comprise bond structures capable of forming self-passivating interconnects. In one embodiment, the bond structures 813, 823 are formed according to any of the embodiments described in FIGS. 1 through 5B and the accompanying text above. However, it should be understood that the disclosed embodiments of a method and apparatus for bonding wafers are not limited to self-passivating interconnects and, in a further embodiment, the bond structures 813, 823 are not self-passivating.

Referring to block 720 in FIG. 7, uniform contact is provided across the interface between the mating bond structures. As used herein, the phrase “uniform contact” should not be interpreted to require perfectly uniform contact (or even substantially uniform contact) across the interface between each pair of mating bond structures. Rather, the phrase “uniform contact” may be interpreted as any degree of contact sufficient to carry out the disclosed embodiments. In some embodiments, substantially uniform contact may be sufficient to perform the disclosed embodiments; however, uniform or substantially uniform contact is not a requirement for all embodiments. Thus, no unnecessary limitations should be ascribed to the phrase “uniform contact”.

According to one embodiment, uniform contact is created by applying pressure (P) 805 to the aligned and stacked substrates 810, 820, which is also illustrated in FIG. 8A. In one embodiment, a pressure (P) of between 0.01 MPa and 1.0 MPa is applied to the substrates 810, 820 to achieve uniform contact. In other embodiments, a pressure in a range up to 5.0 MPa is applied to the substrates 810, 820 to create uniform contact.

In another embodiment, one or both of the substrates 810, 820 are heated to a temperature at which the substrate(s) become less brittle. At this temperature, the substrate(s) may be more compliant and flexible, which can assist in the formation of uniform contact across the interface 890 between the mating bond structures 813, 823. In one embodiment, the substrate(s) are heated to a temperature at which they can flex to an extent sufficient to provide uniform contact across the interface 890 between the mating bond structures 813, 823; however, this temperature is below that temperature at which bonding (and diffusion) between the mating bond structures will occur.

According to another embodiment, in order to assist in the formation of uniform contact between the substrates, one or both of the substrates is thinned. This is illustrated in FIG. 8B, where a backside 812 of the first substrate 810 has been thinned. Due to a smaller thickness, the thinned wafer 810 is more compliant and hence more flexible, and this increased flexibility can assist in the formation of uniform contact across the interface 890 between the mating bond structures 813, 823. In one embodiment, the first substrate 810 has an original thickness of between 500 μm and 1,000 μm, and this substrate is thinned to a final thickness (T) of between 1 μm and 300 μm. Any suitable process, such as chemical-mechanical polishing (CMP) or etching, may be employed to thin one or both of the substrates.

According to yet another embodiment, the formation of uniform contact between the mating bond structures may be assisted by the use of a CTE matching layer. This is illustrated in FIG. 8C, where a CTE (Coefficient of Thermal Expansion) matching layer 850 has been disposed over the backside 812 of the first substrate 810 (and between this substrate and the bonding apparatus used to apply pressure to the wafer stack). The CTE matching layer 850 can compensate for differences in thermal expansion rates between the substrate(s) and bonding apparatus, reducing thermally induced stresses in the substrates 810, 820. Reducing these thermal stresses can enable the substrate 810 (and perhaps substrate 820) to flex sufficiently during the formation of contact between the mating bond structures 813, 823—as well as to remain in a flexed state under pressure during bonding—without fracture. In one embodiment, the CTE matching layer 850 comprises a material having a CTE value that is in a range between a CTE of the bonding apparatus and a CTE of the substrate 810. In another embodiment, the CTE matching layer 850 has a CTE that is greater than the CTE of the bonding apparatus and that is less than the CTE of the substrate 810. The CTE matching layer 850 may comprise any suitable material or combination of materials, including a metal, ceramic, and/or composite material. Also, although just one CTE matching layer is shown in FIG. 8C, in other embodiments, a second CTE matching layer may be placed between the second substrate 820 and the bonding apparatus.

It should be understood that any combination of the aforementioned embodiments may be used in combination to create uniform contact between the mating bond structures 813, 823 of the first and second substrates 810, 820. For example, as shown in FIG. 8D, the backside 812 of first wafer 810 has been thinned, as described above. In addition, a CTE matching layer 850 has been disposed between the first wafer backside 812 and the bonding apparatus used to apply a pressure (P) 805 to the stacked substrates 810, 820. In a further embodiment, one or both of the substrates 810, 820 is heated to a temperature at which the substrate(s) are relatively more flexible (but below the temperatures at which bonding and diffusion can occur), as previously described.

Returning to FIG. 7, the substrates and mating bond structures are ramped to a bond temperature, as set forth in block 730. At the bond temperature, bonds (e.g., metal-to-metal bonds) between the mating bond structures 813, 823 can form, as set forth in block 740. Each pair of bond structures 813, 823, when bonded together, may form an interconnect between the first and second substrates 810, 820. Referring to block 750, the substrates are maintained at an elevated temperature in order to allow diffusion of a metal to free surfaces of the interconnects, such that a passivation layer can be formed on each of the interconnects. This is illustrated in FIG. 8E, which shows a number of interconnects 830 extending between the first and second substrates 810, 820, each interconnect 830 created from a bonded pair of mating bond structures 813, 823. Further, each interconnect 830 includes a passivation layer 840 formed by the diffusion of a metal (e.g., aluminum) to free surfaces of the interconnect (comprised of, for example, copper). The diffusion of a metal to free surfaces of the interconnects in order to form the passivation layer is described above in FIGS. 1 through 5B and the accompanying text. Embodiments of the temperature profile over which bonding and diffusion can occur (blocks 730 through 750 in FIG. 7) are shown in each of FIGS. 9A and 9B, which are now discussed in turn.

Referring first to FIG. 9A, a graph 900a of temperature (T) as a function of time (t) is shown. A curve 904a representing one embodiment of a temperature profile over which bonding can be performed is shown on the graph 900a. At some time t₁, heating begins until a temperature T* is achieved, which occurs at a later time t₂. The temperature T* is, in one embodiment, a temperature at which one or both of the substrates is sufficiently heated to become less rigid and relatively more flexible, in order to assist in the formation of uniform contact between the mating bond structures 813, 823. However, in one embodiment, the temperature T* is less than a temperature at which bonding and diffusion will occur. According to one embodiment, when temperature T* is achieved, a pressure is applied to the stacked substrates 810, 820 (as denoted in FIG. 9A by the arrow labeled P). In one embodiment, the temperature T* comprises a temperature in a range between 100 and 300 degrees Celsius. In a further embodiment, the temperature T* comprises a temperature in a range up to 450 degrees Celsius.

At some later time t₃, additional heating commences to heat the mating bond structures 813, 823 to a temperature T_{BOND} at which bonding can take place, which occurs at a later time t₄. According to one embodiment (e.g., where the mating bond structures comprise copper), the bond temperature T_{BOND} comprises a temperature in a range between 200 and 450 degrees Celsius. The mating bond structures 813, 823 (and substrates 810, 820) are maintained at T_{BOND} for a time sufficient to allow for the formation of bonds (e.g., metal-to-metal bonds) between the mating bond structures 813, 823, such that interconnects are formed between the substrates 810, 820. Thus, at some later time t₅, bonding has been achieved. The time period during which bonding may take place is denoted in FIG. 9A as t_{BOND}.

As noted above, after bonding, an elevated temperature is maintained in order to allow sufficient diffusion to occur, such that the formation of a passivation layer on the interconnects can take place. This is shown in FIG. 9A, wherein an elevated temperature is maintained until a subsequent time t₆ in order for diffusion to take place. The time period over which diffusion may take place is denoted in FIG. 9A as t_{DIFF}. It should be noted that some diffusion will also occur during bonding (e.g., between times t₄ and t₅ in FIG. 9A). In one embodiment, as shown in FIG. 9A, the elevated temperature at which diffusion is allowed to continue is substantially the same as (or equal to) the bond temperature T_{BOND}. However, in other embodiments, the elevated diffusion temperature may be greater than or less than the bonding temperature. After the formation of a passivation layer over the interconnects, the substrate stack is allowed to cool (as shown by the curve 904a after time t₆).

Turning next to FIG. 9B, a graph 900b of temperature (T) as a function of time (t) is shown. A curve 904b representing another embodiment of a temperature profile over which bonding can be performed is shown on the graph 900b. At some time t₁, heating begins until a bond temperature T_{BOND} is achieved, which occurs at a later time t₂. As previously noted, in one embodiment, the bond temperature T_{BOND} comprises a temperature in a range between 200 and 450 degrees Celsius. The mating bond structures 813, 823 (and substrates 810, 820) are maintained at T_{BOND} for a time sufficient to allow for the formation of bonds (e.g., metal-to-metal bonds) between the mating bond structures 813, 823, such that interconnects are formed between the substrates 810, 820. At some later time t₃ bonding has been achieved. The time period during which bonding may take place is denoted in FIG. 9B as t_{BOND}. Also, in a further embodiment, prior to heating, a pressure is applied to the stacked substrates 810, 820 (as denoted in FIG. 9B by the arrow labeled P).

Once again, after bonding, an elevated temperature is maintained in order to allow sufficient diffusion to occur, such that the formation of a passivation layer on the interconnects can take place. This is shown in FIG. 9B, wherein an elevated temperature is maintained until a subsequent time t₄ in order for diffusion to take place. The time period over which diffusion may take place is denoted in FIG. 9B as t_{DIFF}. As noted above, some diffusion may also occur during bonding (e.g., between times t₂ and t₃ in FIG. 9B). In one embodiment, as shown in FIG. 9B, the elevated temperature at which diffusion is allowed to continue is substantially the same as (or equal to) the bond temperature T_{BOND}. However, in other embodiments, the elevated diffusion temperature may be greater than or less than the bonding temperature. After the formation of a passivation layer over the interconnects, the substrate stack is allowed to cool (as shown by the curve 904b after time t₄).

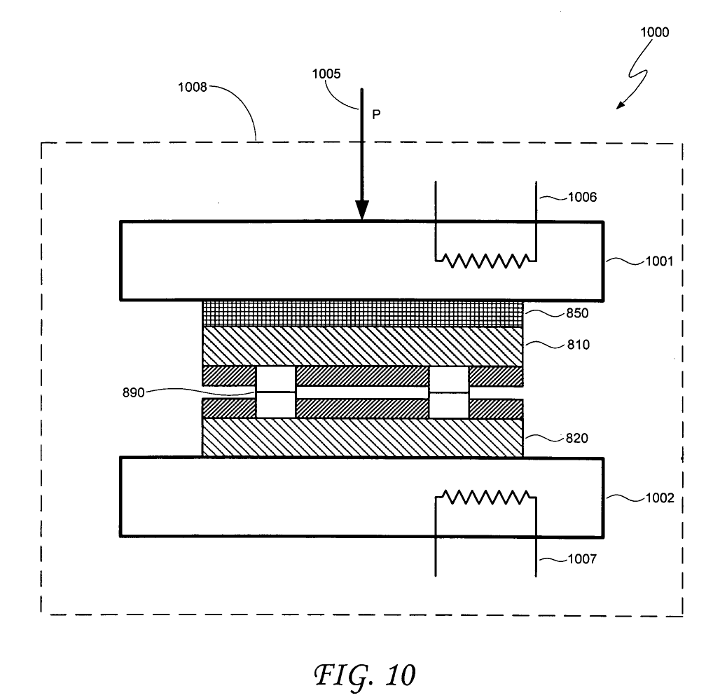

Referring to FIG. 10, illustrated is an embodiment of a wafer bonding apparatus 1000. The bonding apparatus 1000 includes a first wafer holding device 1001 and a second wafer holding device 1002. Each of the wafer holding devices 1001, 1002 comprises any device capable of holding a wafer (or other substrate) for a bonding process. By way of example, the wafer holding devices 1001, 1002 may each comprise an electrostatic chuck, a vacuum chuck, or a wafer carrier (wherein a layer of adhesive may be used to secure a wafer to the carrier).

In one embodiment, one or both of the wafer holding devices 1001, 1002 may be coupled with a motion device (not shown in figures) capable of moving the holding devices relative to one another such that a compressive force—and, hence, a pressure (P) 1005—can be applied to a pair of wafers disposed between the holding devices. Such a motion device (or devices) may also be used to align the mating bond structures of a pair of wafers disposed in the bonding apparatus. Also, in yet another embodiment, one or both of the wafer holding devices 1001, 1002 may include a heating device (e.g., holding device 1001 may include heating device 1006 and/or holding device 1002 may include heating device 1007). The heating devices 1006, 1007 may be used to heat a pair of wafers and their mating bond structures to the bond temperature, as well as to the elevated diffusion temperature (and perhaps to the temperature T* of FIG. 9A).

In a further embodiment, the bonding apparatus 1000 includes a chamber 1008 in which the wafer holding devices 1001, 1002 are disposed. According to one embodiment, the chamber 1008 is capable of maintaining an environment during wafer bonding including oxygen. According to another embodiment, the chamber 1008 is capable of maintaining an environment during wafer bonding including nitrogen. According to a further embodiment, the chamber 1008 is capable of maintaining substantially a vacuum during wafer bonding.

In one embodiment, the method of bonding wafers described in FIGS. 7 through 9B and the accompanying text above can be performed using the bonding apparatus 1000 of FIG. 10. For example, as shown in FIG. 10, the first substrate 810 may be secured to the first wafer holding device 1001, whereas the second substrate 820 may be secured to the second wafer holding device 1002. According to one embodiment, a CTE matching layer 850 may be disposed between the first substrate 810 and the first wafer holding device 1001 (and, in a further embodiment, a second CTE matching layer may be disposed between the second substrate 820 and the second wafer holding device 1002).

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

1. A method comprising:
aligning a number of bond structures on a first substrate with a mating number of bond structures on a second substrate;
providing uniform contact between the mating bond structures of the first and second substrates;
heating the mating bond structures to a first temperature, wherein bonds form between the mating bond structures at the first temperature, the bonded mating bond structures forming a number of interconnects; and
heating the interconnects to a second temperature at which diffusion of an element within the interconnects occurs and maintaining the second temperature for a time sufficient to allow diffusion of the element to free surfaces of the interconnects to form a passivation layer.

2. The method of claim 1, wherein the second temperature is substantially equal to the first temperature.

3. The method of claim 1, wherein the second temperature is less than or greater than the first temperature.

4. The method of claim 1, wherein the first temperature comprises a temperature up to approximately 450 degrees Celsius.

5. The method of claim 1, wherein the second temperature comprises a temperature up to approximately 450 degrees Celsius.

6. The method of claim 1, wherein providing uniform contact between the mating bond structures comprises applying a pressure to the first and second substrates.

7. The method of claim 6, wherein the pressure comprises up to 5.0 MPa.

8. The method of claim 6, further comprising thinning a backside of at least one of the first and second substrates.

9. The method of claim 1, further comprising placing a coefficient of thermal expansion (CTE) matching layer between a backside of the first substrate and a bonding apparatus.

10. The method of claim 9, further comprising placing another CTE matching layer between a backside of the second substrate and the bonding apparatus.

11. The method of claim 1, wherein each of the first and second substrates comprises a semiconductor wafer upon which integrated circuitry for a number of die has been formed.

12. The method of claim 1, wherein the interconnects comprise copper and the passivation layer comprises aluminum.

13. A method comprising:
aligning a number of bond structures on a first substrate with a mating number of bond structures on a second substrate;
heating at least one of the first and second substrates to an initial temperature, the at least one substrate being relatively more flexible at the initial temperature;
applying a pressure to the first and second substrates to create uniform contact between the mating bond structures of the first and second substrates;
heating the mating bond structures to a bond temperature, wherein bonds form between the mating bond structures at the bond temperature, the bonded mating bond structures forming a number of interconnects; and
heating the interconnects to a diffusion temperature to allow diffusion of an element within the interconnects and maintaining the diffusion temperature for a time sufficient to allow diffusion of the element to free surfaces of the interconnects to form a passivation layer.

14. The method of claim 13, wherein the bond temperature is substantially equal to the diffusion temperature.

15. The method of claim 13, wherein the bond temperature is less than or greater than the diffusion temperature.

16. The method of claim 13, wherein the initial temperature is less than the bond temperature and is less than the diffusion temperature.

17. The method of claim 13, wherein the bond temperature comprises a temperature up to approximately 450 degrees Celsius.

18. The method of claim 13, wherein the diffusion temperature comprises a temperature up to approximately 450 degrees Celsius.

19. The method of claim 13, wherein the initial temperature comprises a temperature up to approximately 450 degrees Celsius.

20. The method of claim 13, wherein the pressure comprises up to 5.0 MPa.

21. The method of claim 13, further comprising thinning a backside of at least one of the first and second substrates.

22. The method of claim 13, further comprising placing a coefficient of thermal expansion (CTE) matching layer between a backside of the first substrate and a bonding apparatus.

23. The method of claim 22, further comprising placing another CTE matching layer between a backside of the second substrate and the bonding apparatus.

24. The method of claim 13, wherein each of the first and second substrates comprises a semiconductor wafer upon which integrated circuitry for a number of die has been formed.

25. The method of claim 13, wherein the interconnects comprise copper and the passivation layer comprises aluminum.

26-30. (canceled)
